(19) United States
(12) Patent Application Publication
(10) Pub. No.: US 2010/0055321 A1
(43) Pub. Date: Mar. 4, 2010

(54) PRECURSORS FOR ATOMIC LAYER DEPOSITION

(76) Inventors: Ce Ma, San Diego, CA (US); Qing Min Wang, North Andover, MA (US)

Correspondence Address: The BOC Group, Inc., 575 MOUNTAIN AVENUE, MURRAY HILL, NJ, 07974-2082, US

(21) Appl. No.: 12/374,414

(22) PCT Filed: Jul. 12, 2007
(86) PCT No.: PCT/US07/15847

§ 371 Date: Nov. 2, 2009

Related U.S. Application Data
(60) Provisional application No. 60/832,561, filed on Jul. 21, 2006.

(51) Int. Cl. C23C 16/448; C09D 1/00

(52) U.S. Cl. 427/255.394; 106/286.4; 106/286.1; 106/287.18; 106/287.19

(57) ABSTRACT

Stable ALD precursors that have at least one metal-nitrogen bond and a mixed ligand are presented. These ALD precursors exhibit self-limiting growth, at reduced deposition temperature and produce less contamination all with enhanced stability.

### CROSS REFERENCE TO RELATED APPLICATIONS

This application claims priority from international application Ser. No. PCT/US2007/015847, filed 12 Jul. 2007 (published as WO 2008/013675 A2, with publication date 31 Jan. 2008), which claims priority from U.S. Application No. 60/832,561 filed 21 Jul. 2006.

### FIELD OF THE INVENTION

The present invention relates to new and useful precursors for atomic layer deposition.

### BACKGROUND OF THE INVENTION

Atomic layer deposition (ALD) is an enabling technology for next generation conductor barrier layers, high-k gate dielectric layers, high-k capacitance layers, capping layers, and metallic gate electrodes in silicon wafer processes. ALD has also been applied in other electronics industries, such as flat panel display, compound semiconductor, magnetic and optical storage, solar cell, nanotechnology and nanomaterials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

A typical ALD process uses sequential precursor gas pulses to deposit a film one layer at a time. In particular, a first precursor gas is introduced into a process chamber and produces a monolayer by reaction at surface of a substrate in the chamber. A second precursor is then introduced to react with the first precursor and form a monolayer of film made up of components of both the first precursor and second precursor, on the substrate. Each pair of pulses (one cycle) produces exactly one monolayer of film allowing for very accurate control of the final film thickness based on the number of deposition cycles performed.

As semiconductor devices continue to get more densely packed with devices, channel lengths also have to be made smaller and smaller. For future electronic device technologies, such as 90 nm technology, it will be necessary to replace SiO₂ and SiON gate dielectrics with ultra thin high-k oxides having effective oxide thickness (EOT) less than 1.5 nm. Preferably, high-k materials should have high band gaps and band offsets, high k values, good stability on silicon, minimal SiO₂ interface layer, and high quality interfaces on substrates. Amorphous or high crystalline temperature films are also desirable. Some acceptable high-k dielectric materials are listed in Table 1. Among those listed, HfO₂, Al₂O₃, ZrO₂, and the related ternary high-k materials have received the most attention for use as gate dielectrics. HfO₂ and ZrO₂ have higher k values but they also have lower break down fields and crystalline temperatures. The aluminates of Hf and Zr possess the combined benefits of higher k values and higher break down fields. Y₂O₃ has high solubility of rare earth materials (e.g. Eu⁺³) and is useful in optical electronics applications.

TABLE 1
Dielectric properties of ALD high-k gate materials

| | | EOT | | Crystalline |
|---|---|---|---|---|
| | | (@ 5 nm | Break down Field E_{BD} | Temp |
| Material | K | film) | (MV/cm @ 1 μA/cm² | (° C.) |
| HfO₂ | 13-17 | 1.3 | 1-5 | 400-600 |
| Al₂O₃ | 7-9 | 2.44 | 3-8 | 900-1000 |
| ZrO₂ | 20 | 0.98 | 1 | <300 * |
| HfₓAl_{y}O_{z} | 8-20 | 1.22 | N/A | 900 |
| ZrₓAl_{y}O_{z} | 8-20 | 1.22 | N/A | 975 |
| Y₂O₃ | 12-15 | 1.44 | 4 | <600 |
| Ta₂O₅ | 23-25 | 0.81 | 0.5-1.5 | 500-700 |
| NbₓAl_{y}O_{z} | 8 | 2.44 | 5 | N/A |
| HfₓSi_{y}O_{z} | N/A | N/A | N/A | 800 |
| TaₓTi_{y}O_{z} | 27-28 | 0.71 | 1 | N/A |
| Al₂O₃/HfO₂ | N/A | N/A | N/A | N/A |
| Al₂O₃/TiO₂ | 9-18 | 1.44 | 5-7 | N/A |

* as a function of film thickness

Several types of traditional vapor phase deposition precursors have been tested in ALD processes, but generally suffer from one or more disadvantages. These disadvantages include the requirement for high temperature deposition, causing particle contamination at the substrate, and lack of stability.

For ALD processes, the precursors should have good volatility and be able to saturate the substrate surface quickly through chemisorptions and surface reactions. The ALD half reaction cycles should be completed within 5 seconds, preferably within 1 second. The exposure dosage should be below 10⁸ Laugmuir (1 Torr*sec=10⁶ Laugmuir). The precursors should be stable within the deposition temperature windows, because uncontrollable CVD reactions could occur when the precursor decomposes in gas phase. The precursors themselves should also be highly reactive so that the surface reactions are fast and complete. In addition, complete reactions yield good purity in films. The preferred properties of ALD precursors are given in Table 2.

TABLE 2
Preferred ALD precursor properties

| Requirement | | |
|---|---|---|
| Class | Property | Range |
| Primary | Good volatility | >0.1 Torr |
| Primary | Liquid or gas | At room temperatures |
| Primary | Good thermal stability | >250° C. or >350° C. in gas phase |
| Primary | Fast saturation | <5 sec or <1 sec |
| Primary | Highly reactive | Complete surface reactive cycles |
| Primary | Non reactive volatile | No product and reagent reaction |
| | byproduct | |
| Secondary | High growth rate | Up to a monolayer a cycle |
| Secondary | Less shield effect from | Free up un-occupied sites |
| | ligands | |
| Secondary | Cost and purity | Key impurity: H₂O, O₂ |
| Secondary | Shelf-life | >1-2 years |
| Secondary | Halides | Free in films |
| Secondary | Carbon | <1% in non carbon containing |
| | | films |

Because of stringent requirements for ALD precursors as noted in Table 2, there remains a need in the art for new types of ALD precursors are needed that are more stable, exhibit higher volatility, and are better suited for ALD.

### SUMMARY OF INVENTION

The present invention provides new classes of stable ALD precursors that include mixed ligands, such as sterically hindered ligands that have at least one metal-nitrogen bond. Metal-oxygen bonds may also be used, but metal-carbon bonds should be avoided. The mixed ligand ALD precursors according to the present invention exhibit self-limiting growth, at reduced deposition temperature and less contamination all at enhanced stability. Stability is increased because of increased ligand saturation around the metal center, thereby preventing hydrolytic thermal decomposition.

### DETAILED DESCRIPTION OF THE INVENTION

The present invention provides ALD precursors having the general formula:

M(NR¹ₘ)ₙ(NO₃)ₚ(NO₃₋ₛR²ₛ)_{y-p}X_{q}

where M is a main group or transition metal, R¹ is a C1 to C8 hydrocarbon, silyl or boron group, R² is OH or other hydroxide group, X is a group VIIA halide, m=1 to 3, s=0 to 3, n, p, q, y=0 to 5, and sum of n, p, q is less than or equal to 5. In particular, M may be Hf, Ti, Ta or the like, and X may be F, Cl, Br or I.

In accordance with the present invention, partially hydrated nitrates exhibit ALD reactivity and protect against moisture attack. Fully hydrated materials may stabilize anhydride nitrate but do not have high volatility and reactivity. Example of partially hydrated nitrates according to the present invention include those having the general formula

M(NO₃)ₚ((NO₃₋ₛ)(OH)ₛ)₁₋ₚ

where M, p and s are the same as defined above. Specific examples include Hf(NO₃)₃(NO₃H) and Hf(NO₃)₂(NO₃H)₂.

Mixed nitrate and halide precursors are also examples of the present invention. These precursors have the general formula

M(NO₃)ₘXₙ

where M, X, m and n are as defined above. Precursors according to this formula have self-limiting surface reactions and increased thermal stability. Specific examples of these precursors are Hf(NO₃)₃Cl and Hf(NO₃)₂Cl₂. An ALD reaction cycle using such precursors can be carried out as follows:

1^{st} half cycle: Hf(NO₃)₂Cl₂(g)+2OH(a)→O₂—Hf(NO₃)₂(a)+2HCl(g)

2^{nd} half cycle: O₂—Hf(NO₃)₂(a)+2H₂O(g)→O₂—Hf(OH)₂(a)+2H(NO₃)(g)

where (g) and (a) stand for gaseous and adsorbed chemical species, respectively.

Another example of precursors according to the present invention are mixed nitrate and amide precursors of the general formula:

M(NR¹ₘ)ₙ(NO₃)ₚ(NO₃₋ₛR²ₛ)_{y-p}

where M, R¹, R², m, n, p, s and y are as defined above. These precursors avoid halide contamination and provide increased precursor volatility at lower deposition temperatures. The Specific examples include Hf(NMe₂)₂(NO₃)₂Hf(NEtMe)₂ (NO₃)₂ and Hf(N(SiMe₃)₂)₂(NO₃)₂. An ALD reaction cycle using such precursors can be described as:

1^{st} half cycle: Hf(NMe₂)₂(NO₃)₂(g)+2OH(a)→O₂—Hf(NMe₂)₂(a)+2H(NO₃)(g)

2^{nd} half cycle: O₂—Hf(NMe₂)₂(a)+2H₂O(g)→O₂—Hf(OH)₂(a)+2HNMe₂(g)

where (g) and (a) stand for gaseous and adsorbed chemical species, respectively.

For ALD processes it is beneficial to deliver the precursors in liquid form. However, some useful precursors are in solid form at room temperature. Delivery of solid precursors requires a heat source that may cause thermal decomposition of the precursor as well as particulate contamination of the thin film formed. In order to avoid these disadvantages, a solid precursor may be dissolved in a solvent. This can both stabilize the precursor and increase shelf-life. Useful solvents must be inert in the ALD process, i.e. can not cause film contamination. Examples of a precursor and solvent combination according to the present invention include, but are not limited to Hf(NO₃)₄ in ethyl acetate, acetonitrile, dimethyl sulfide, triethylamine, dimethoxyethane (DME), 1,4-dioxane, tetraiiethylethylenediamine, or the like.

ALD precursors according to the present invention may be used to produce high-k layers of metal silicates (MₓSi_{y}O_{z}) and metal aluminates (MₓAl_{y}O_{z}) where x, y and z are vary based on the mole fractions of M and Si or M and Al. In the case of metal silicates, n*x+4y=2z and for metal alurminates, n*x+3y=2z, where n is the valency or oxidation state of the metal M. The mole fractions of the metal M and the Si or Al component can vary between 0 and 100% depending on the film desired (such that x+y=z). This means that x=0 to 1; y=1−x; z=(n*x+4y)/2 for silicates; and z=(n*x+3y)/2 for aluminates. This can further be simplified to z=((n−4)*x+4)/2 for silicates and z=((n−3)*x+3)/2 for aluminates. These ternary high-k materials combine the desirable properties of high k values and low leakage currents. For example, HfₓAl_{y}O_{z} gives the combined benefits of k values of HfO₂ and higher crystalline temperature of Al₂O₃. However, depositing ternary oxides with simple ALD processes is difficult.

To overcome this problem, the present invention provides methods of deposition using precursors according to the present invention. In particular, in a first embodiment, nano-laminates of simple oxides may be deposited and are then annealed to form mixed oxides. This method requires pulsing mixtures of metal and silicon or metal and aluminum ALD precursors into the deposition tools at the same time. In a second embodiment of the present invention, integrated precursors having the formula M(NR³)ₙR⁴_{y} wherein M, n and y are as defined above and wherein R³ and R⁴ are silicon or aluminum containing groups can be used. Examples of these precursors include Hf(NMe₂)₂(OAlEt₂)₂, Hf(NMe₂)₂(OSiMe₃)₂, and Hf(N(SiMe₃)₂)₄. An ALP reaction cycle using such precursors is as follows:

1^{st} half cycle: Hf(NMe₂)₂(OAlEt₂)₂(g)+2OH(a)→O₂—Hf(OAlEt₂)₂(a)+2H(N Me₂)(g)

2^{nd} half cycle: O₂—Hf(OAlEt₂)₂(a)+2O(g)→O₂—Hf(OAlOH)₂(a)+2(H₂C═CH₂)(g)

where (g) and (a) stand for gaseous and adsorbed chemical species, respectively.

The present invention provides new classes of stable ALD precursors that have at least one metal-nitrogen bond and a mixed ligand. The ALD precursors according to the present invention exhibit self-limiting growth, at reduced deposition temperature and produce less contamination all with enhanced stability.

It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. Precursors for atomic layer deposition having the formula:
M(NR¹ₘ)ₙ(NO₃)ₚ(NO₃₋ₛR²₅)_{y-p}X_{q}
where M is a main group or transition metal; R¹ is a C1 to C8 hydrocarbon, silyl or boron group; R² is OH or other hydroxide group; X is a group VIIA halide; m=1 to 3; s=0 to 3; n, p, q, y=0 to 5; and the sum of n, p, q is less than or equal to 5.

2. Precursors according to claim 1, wherein M is Hf, Ti, or Ta.

3. Precursors according to claim 1, wherein X is F, Cl, Br or I.

4. Precursors for atomic layer deposition having the formula:
M(NO₃)ₚ((NO₃₋ₛ)(OH)ₛ)₁₋ₚ
where M is a main group or transition metal; s=0 to 3; and p=0 to 5.

5. Precursors according to claim 4, wherein M is Hf, Ti, or Ta.

6. Precursors according to claim 4, wherein the precursor is Hf(NO₃)₃(NO₃H) or Hf(NO₃)₂(NO₃H)₂.

7. Precursors for atomic layer deposition having the formula:
M(NO₃)ₘXₙ
where M is a main group or transition metal; X is a group VIIA halide; m=1 to 3; and n=0 to 5.

8. Precursors according to claim 7, wherein M is Hf, Ti, or Ta.

9. Precursors according to claim 1, wherein X is F, Cl, Br or I.

10. Precursors according to claim 7, wherein the precursor is Hf(NO₃)₃Cl or Hf(NO₃)₂Cl₂.

11. Precursors for atomic layer deposition having the formula:
M(NR¹ₘ)ₙ(NO₃)ₚ(NO₃₋ₛR²ₛ)_{y-p}
where M is a main group or transition metal; R¹ is a C1 to C8 hydrocarbon, silyl or boron group; R² is OH or other hydroxide group; m=1 to 3; s=0 to 3; n, p, y=0 to 5, and the sum of n, p is less than or equal to 5.

12. Precursors according to claim 1, wherein M is Hf, Ti, or Ta.

13. Precursors according to claim 11, wherein the precursor is (NMe₂)₂(NO₃)₂Hf(NEtMe)₂ (NO₃)₂ or Hf(N(SiMe₃)₂)₂(NO₃)₂.

14. Precursors for atomic layer deposition having the formula:
M(NR³)ₙR⁴_{y}
where M is a main group or transition metal; R³ and R⁴ are silicon or aluminum containing groups, and n, y=0 to 5.

15. Precursors according to claim 14, wherein M is Hf, Ti, or Ta.

16. Precursors according to claim 15, wherein the precursor is Hf(NMe₂)₂(OAlEt₂)₂, Hf(NMe₂)₂(OSiMe₃)₂, or Hf(N(SiMe₃)₂)₄.

17. An ALD reaction cycle comprising:
a first half cycle: Hf(NO₃)₂Cl₂(g)+2OH(a)→O₂—Hf(NO₃)₂(a)+2HCl(g) and
a second half cycle: O₂—Hf(NO₃)₂(a)+2H₂O(g)→O₂—Hf(OH)₂(a)+2H(NO₃)(g)
wherein (g) and (a) stand for gaseous and adsorbed chemical species, respectively.

18. An ALD reaction cycle comprising:
a first half cycle: Hf(NMe₂)₂(NO₃)₂(g)+2OH(a)→O₂—Hf(NMe₂)₂(a)+2H(NO₃)(g) and
a second half cycle: O₂—Hf(NMe₂)₂(a)+2H₂O(g)→O₂—Hf(OH)₂(a)+2HNMe₂(g)
wherein (g) and (a) stand for gaseous and adsorbed chemical species, respectively.

19. An ALD reaction cycle comprising:
a first half cycle: Hf(NMe₂)₂(OAlEt₂)₂(g)+2OH(a)→O₂—Hf(OAlEt₂)₂(a)+2H(N Me₂)(g) and
a second half cycle: O₂—Hf(OAlEt₂)₂(a)+2O(g)→O₂—Hf(OAlOH)₂(a)+2(H₂C═CH₂)(g)
wherein (a) and (a) stand for gaseous and adsorbed chemical species, respectively.
